(19) United States
(12) Patent Application Publication
(10) Pub. No.: US 2026/0171995 A1
(43) Pub. Date: Jun. 18, 2026

(54) DOUBLE FILTERING BASED SPIN ELEMENT, METHOD THEREOF, AND SPINTRONICS DEVICE INCLUDING THE SAME

(71) Applicant: UIF (University Industry Foundation), Yonsei University, Seoul (KR)

(72) Inventors: Jongill HONG, Seoul (KR); Taehui NA, Incheon (KR)

(21) Appl. No.: 19/004,640

(22) Filed: Dec. 30, 2024

(30) Foreign Application Priority Data
Dec. 13, 2024 (KR) 10-2024-0185662
Dec. 27, 2024 (KR) 10-2024-0199014

(51) Int. Cl. H03H 2/00

(52) U.S. Cl. CPC H03H 2/001

(57) ABSTRACT

Provided is a double-filtering-based spin element. The double-filtering-based spin element includes a first magnetic layer, a second magnetic layer, a spin-to-charge conversion layer formed between the first magnetic layer and the second magnetic layer and generating an electric field by performing spin-orbit coupling on first passing electrons and reflected electrons, a first spin injection layer configured to receive the first passing electrons that have passed through the first magnetic layer and inject the electrons into the spin-to-charge conversion layer, and a second spin injection layer configured to receive the reflected electrons reflected from the second magnetic layer among second passing electrons that have passed through the spin-to-charge conversion layer and inject the reflected electrons into the spin-to-charge conversion layer.

### CROSS-REFERENCE TO RELATED APPLICATIONS

This application claims the benefit of priority under 35 U.S.C. § 119(a) to Korean Patent Application No. 10-2024-0185662, filed on Dec. 13, 2024, and Korean Patent Application No. 10-2024-0199014, filed on Dec. 27, 2024, in the Korean Intellectual Property Office, the disclosure of which is incorporated herein in its entirety by reference.

### BACKGROUND

The present disclosure relates to a spin element, and more particularly, to a spin-to-charge conversion and double-filtering-based spin element, which may increase a sensing margin by using a double ferromagnetic structure and stably transmit data to a next logic circuit, an operating method thereof, and a spintronics device including the spin element.

Spintronics uses spin elements that use spin, a unique momentum of electrons in a specific direction, as a basic unit of information storage and processing.

A spin element refers to an electronic device that operates by utilizing two physical properties of electrons, such as spin and charge. Electrons have a physical property called spin that is quantum mechanically unique. Spin may have a +½ up state or a −½ down state.

### SUMMARY

An object of the present disclosure is to provide a spin element capable of performing spin-to-charge conversion and double-filtering to increase a sensing margin by using a double ferromagnetic structure and stably transmit data to a next logic circuit, an operating method thereof, and a spintronics device including the spin element.

An exemplary embodiment of the present disclosure is directed to a double-filtering-based spin element, including a first magnetic layer, a second magnetic layer, a spin-to-charge conversion layer formed between the first magnetic layer and the second magnetic layer and generating an electric field by performing spin-orbit coupling on first passing electrons and reflected electrons, a first spin injection layer configured to receive the first passing electrons that have passed through the first magnetic layer and inject the electrons into the spin-to-charge conversion layer, and a second spin injection layer configured to receive the reflected electrons reflected from the second magnetic layer among second passing electrons that have passed through the spin-to-charge conversion layer and inject the reflected electrons into the spin-to-charge conversion layer.

Another exemplary embodiment of the present disclosure is directed to a spintronics device, including a first stage, a second stage, and a conductive channel connected to the first stage and the second stage, in which the first stage includes a first magnetic layer including a first portion and a second portion, a second magnetic layer including a third portion and a fourth portion, a first spin-to-charge conversion layer formed between the first portion and the third portion and generating a first electric field by performing spin-orbit coupling on the first passing electrons and the first reflected electrons, a first spin injection layer formed between the first portion and the first spin-to-charge conversion layer and injecting the first passing electrons that have passed through the first magnetic layer into the first spin-to-charge conversion layer, and a second spin injection layer formed between the first spin-to-charge conversion layer and the third portion and injecting the first reflected electrons reflected from the second magnetic layer among second passing electrons that have passed through the first spin-to-charge conversion layer into the first spin-to-charge conversion layer.

Still another exemplary embodiment of the present disclosure is directed to a method for operating a double-filtering-based spin element, including supplying electrons filtered by a first ferromagnet having a first magnetization direction to a spin-to-charge conversion layer, generating a first electric field as spin-orbit coupling is performed on the filtered electrons in the spin-to-charge conversion layer, supplying reflected electrons reflected by a second ferromagnet having a second magnetization direction among electrons that have passed through the spin-to-charge conversion layer to the spin-to-charge conversion layer, and generating a second electric field by additionally performing spin-orbit coupling on the reflected electrons in the spin-to-charge conversion layer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a structural diagram of a double-filtering-based spin element according to an embodiment of the present disclosure;

FIG. 2 is a conceptual diagram which describes an operation of the double-filtering-based spin element shown in FIG. 1;

FIG. 3 is an embodiment of a spintronics device including the double-filtering-based spin element shown in FIG. 1;

FIG. 4 is a perspective view of a first stage included in the spintronics device shown in FIG. 3 as viewed in a first direction;

FIG. 5 is a front view of the first stage shown in FIG. 4 as viewed in a second direction;

FIG. 6 is another embodiment of the spintronics device including the double-filtering-based spin element shown in FIG. 1;

FIG. 7 is a perspective view of a second stage included in the spintronics device shown in FIG. 6 as viewed in the first direction;

FIG. 8 is a front view of the second stage of FIG. 7 as viewed in the second direction;

FIG. 9 is a block diagram of a semiconductor device including the double-filtering-based spin element shown in FIG. 1; and

FIG. 10 is a flowchart for describing the operation of the double-filtering-based spin element shown in FIG. 1.

### DETAILED DESCRIPTION OF THE EMBODIMENTS

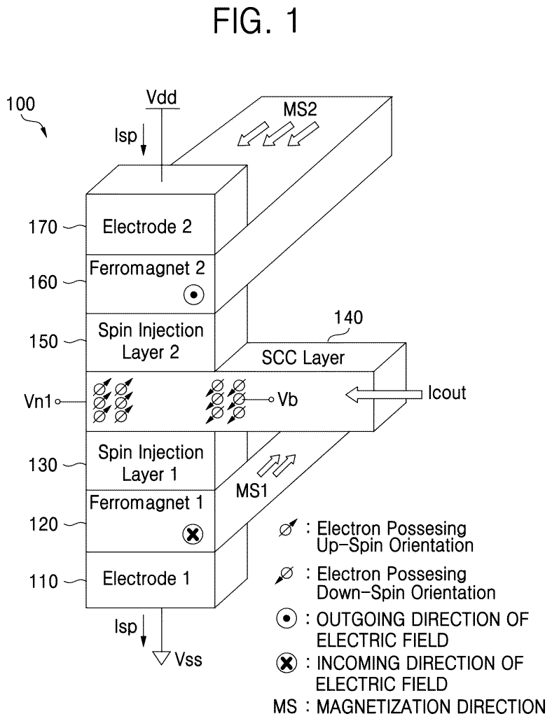

FIG. 1 is a structural diagram of a double-filtering-based spin element according to an embodiment of the present disclosure. Referring to FIG. 1, a double-filtering-based spin element 100 may be included in a spintronics device (or spintronics element) and may also be called a double-ferromagnetic material layer structure. For example, the double-filtering-based spin element 100 may be an output structure or an output portion of a magnetoelectric spin-orbit (MESO) device.

A spintronics device is an electronic device that processes and stores data by utilizing not only charge of an electron but also a spin. A spintronics device is a non-volatile device that retains data even when power is turned off, and may perform fast data processing by utilizing the spin of an electron, consume low power, and store a large amount of data in a miniaturized structure.

The double-filtering-based spin element (or double-filtering-based spin logic element) 100 includes a first electrode 110, a first magnetic layer 120 stacked (also referred to as ‘formed,’ ‘contacted,’ or ‘placed’) on the first electrode 110, a first spin injection layer 130 stacked on the first magnetic layer 120, a spin-to-charge conversion (SCC) layer 140 stacked on the first spin injection layer 130, a second spin injection layer 150 stacked on the SCC layer 140, a second magnetic layer 160 stacked on the second spin injection layer 150, and a second electrode 170 stacked on the second magnetic layer 160.

The stacked elements 110 to 170 may also refer to an output portion of the double-filtering-based spin element 100.

The first electrode 110 is connected to the ground Vss, and the second electrode 170 has a structure that receives an operating voltage Vdd. A current Isp is supplied from the second electrode 170 to the first electrode 110 through the stacked elements 120 to 160.

Each of the first magnetic layer 120 and the second magnetic layer 160 may be a layer including a ferromagnet or a ferromagnetic material.

Examples of ferromagnets that exist in various forms depending on the element, alloy, oxide, and artificial structure are as follows.
(i) Elemental ferromagnets: for example, iron (Fe), cobalt (Co), nickel (Ni), gadolinium (Gd), or the like,
(ii) Alloy ferromagnets which are ferromagnets made of an alloy of two or more elements: for example, an Fe—Si alloy (Iron-Silicon alloy), alnico which is a permanent magnet alloy containing, in addition to iron (Fe), aluminum (Al), nickel (Ni), and/or cobalt (Co) as main components, or permalloy which is an alloy of nickel (Ni) and iron (Fe),
(iii) Oxide ferromagnets such as ferrite,
(iv) Artificial ferromagnets: materials or structures which are produced using nanotechnology and thin-film fabrication techniques, and
(v) Rare-earth ferromagnets (e.g., neodymium magnets, samarium-cobalt magnets, or the like).

When the current Isp flowing from the second electrode 170 to the first electrode 110 through the stacked elements 120 to 160 flows through the ferromagnetic layers 120 and 160, spin polarization occurs according to a magnetization direction of each of the ferromagnetic layers 120 and 160. In this process, a spin-polarized current is generated as spins of charge carriers, influenced by a magnetic orientation of each of the ferromagnetic layers 120 and 160, are aligned in a specific direction.

The first spin injection layer (or first spin current injection layer) 130 may refer to a layer made of a material that may inject electrons that have passed through the first ferromagnetic layer 120 into the SCC layer 140 and generate a spin current. The spin current refers to a current generated when a spin state of an electron (for example, up-spin or down-spin) moves in a specific direction. For example, the first spin injection layer 130 may be a magnetic layer or a ferromagnetic layer that injects electrons into the SCC layer 140 and generates a spin current.

The second spin injection layer (or second spin current injection layer) 150 refers to a layer made of a material that may inject electrons into the SCC layer 140 or a second ferromagnetic layer 160 and generate a spin current. For example, the second spin injection layer 150 may be a magnetic layer or a ferromagnetic layer that injects electrons that have passed through the SCC layer 140 into the second ferromagnetic layer 160 and generates a spin current.

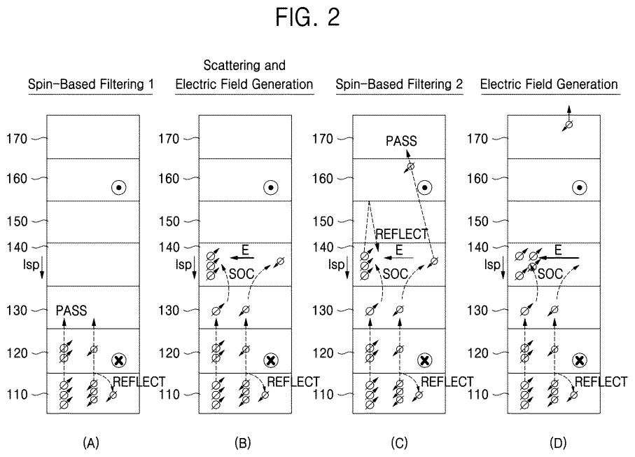

FIG. 2 is a conceptual diagram that describes an operation of the double-filtering-based spin element shown in FIG. 1.

A first spin-based filtering process will be described with reference to FIG. 1 and (A) of FIG. 2. When the current Isp starts to flow from the second electrode 170 to the first electrode 110, conduction electrons start to move from the ground Vss toward the second magnetic layer 120.

When electrons having different spin orientations reach the first ferromagnetic layer 120, a first group of electrons having an up-spin orientation (or a first spin orientation) selectively pass through the first ferromagnetic layer 120 among the electrons, and some of a second group of electrons having a down-spin orientation (or a second spin orientation) pass PASS through the first ferromagnetic layer 120, while some of the second group of electrons are reflected REFLECT from the first ferromagnetic layer 120 among the electrons. At this time, the electrons that have passed through the first ferromagnetic layer 120 are called first passing electrons or first filtered electrons.

For example, in the first spin-based filtering process, among the electrons having different spin orientations, some electrons having a spin orientation different from a magnetization direction of the first ferromagnetic layer 120 are reflected REFLECT, and some electrons having a spin orientation same as the magnetization direction of the first ferromagnetic layer 120 pass PASS through the first ferromagnetic layer 120 among the electrons.

Such a spin-based filtering operation occurs due to unique spin-dependent transport or transmission characteristics in the first ferromagnetic layer 120. At the same time, spin-orbit scattering occurs within the SCC layer 140, and a potential difference is formed due to effects of the spin-orbit scattering and the spin-based filtering, as shown in (B) of FIG. 2.

The SCC layer 140 includes materials capable of converting a spin current into an electrical current or voltage. For example, materials forming the SCC layer 140 may be heavy metals (e.g., platinum (Pt), tantalum (Ta), tungsten (W), or iridium (Ir)) having strong spin-orbit coupling (SOC), topological materials, or ferromagnets, but the materials are not limited thereto.

A scattering and electric field generation process will be described with reference to FIG. 1 and (B) of FIG. 2. Electrons (or first passing electrons) that have passed through the first ferromagnetic layer 120 and the first spin injection layer 130 are scattered according to the spin-orbit coupling (SOC) of the SCC layer 140.

SOC is a physical phenomenon that represents an interaction between the spin of an electron and an orbit motion of the electron. This interaction occurs because, when an electron moves through space, the movement (e.g., orbital angular momentum) of the electron generates a magnetic field, and the spin (e.g., intrinsic angular momentum) of the electron interacts with the magnetic field.

An electric field E is generated in the SCC layer 140 due to a difference in the number of scattered electrons (e.g., between electrons moving to the left and electrons moving to the right in (B) of FIG. 2) according to SOC.

A second spin-based filtering process will be described with reference to FIG. 1 and (C) of FIG. 2. Electrons (e.g., second passing electrons) that have passed through the SCC layer 140 and the second spin injection layer 150 reach the second ferromagnetic layer 160.

When a second magnetization direction MS2 of the second ferromagnetic layer 160 is opposite to a first magnetization direction MS1 of the first ferromagnetic layer 120, the second ferromagnetic layer 160 passes PASS the second group of electrons having a down-spin orientation and reflects or blocks REFLECT the first group of electrons (or reflected electrons) having an up-spin orientation, contrary to an operation of the first ferromagnetic layer 120.

The double-filtering-based spin element 100 has a structure that increases the difference in the number of scattered electrons (for example, between electrons moving to the left and electrons moving to the right in (D) of FIG. 2) according to SOC based on the second spin-based filtering process additionally performed according to the present disclosure, in addition to the first spin-based filtering process.

As the second spin-based filtering process is additionally performed, a difference in density between the electrons having the up-spin orientation and the electrons having the down-spin orientation increases. Due to a second spin-based filtering mechanism, an output voltage in the SCC layer 140 may be significantly increased.

In the double-filtering-based spin element 100, two-time spin-based filtering needs to be performed (or performed sequentially). Accordingly, the first ferromagnetic layer 120 needs to selectively pass electrons having one of the up-spin orientation and the down-spin orientation, and the second ferromagnetic layer 160 needs to selectively pass electrons having the other of the up-spin orientation and the down-spin orientation, and therefore, the first magnetization direction MS1 of the first ferromagnetic layer 120 and the second magnetization direction MS2 of the second ferromagnetic layer 160 need be opposite to each other. Selective pass may mean that some of electrons may be passed and some of the electrons may not be passed.

An electric field generation process will be described with reference to FIG. 1 and (D) of FIG. 2. As the difference in the number of scattered electrons within the SCC layer 140 increases due to the second spin-based filtering process, the electric field E within the SCC layer 140 increases. For example, the electric field E within the SCC layer 140 increases due to an Inverse Spin Hall Effect (ISEE) and/or an Inverse Rashba Edelstein Effect (IREE).

Referring to FIG. 1 and (D) of FIG. 2, a difference between a voltage Vn1 on the left side of the SCC layer 140 and a voltage Vb on the right side, for example, a sensing margin, increases due to the second spin-based filtering process. As shown in FIG. 1, an output current Icout may flow from the right to the left.

Although it is shown in FIGS. 1, 4, 5, and 8 that the first magnetic layer 120 has the first magnetization direction MS1 and the second magnetic layer 160 has the second magnetization direction MS2, when a magnetization direction of the first magnetic layer 120 is the second magnetization direction MS2, a magnetization direction of the second magnetic layer 160 may be the first magnetization direction MS1.

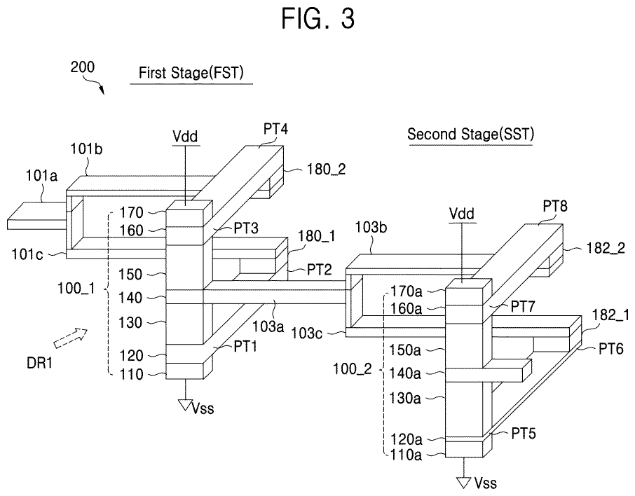

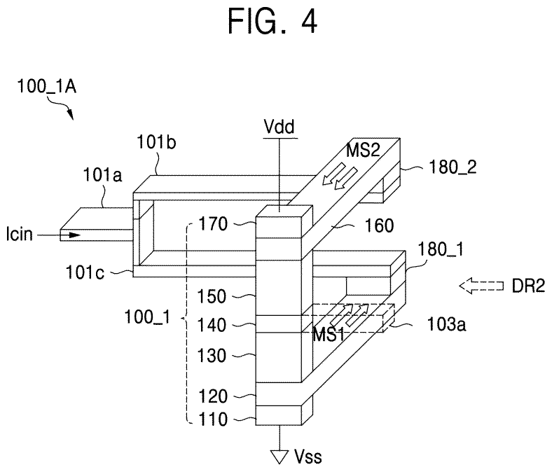

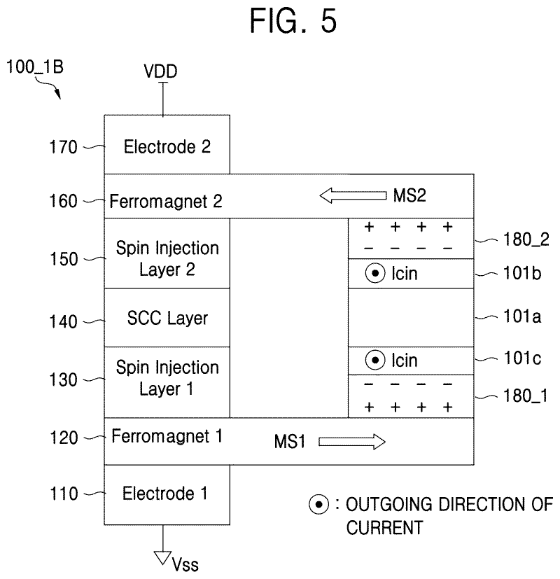

FIG. 3 is an embodiment of a spintronics device including the double-filtering-based spin element shown in FIG. 1, FIG. 4 is a perspective view of a first stage included in the spintronics device shown in FIG. 3 as viewed in a first direction, and FIG. 5 is a front view of the first stage shown in FIG. 4 as viewed in a second direction.

For example, FIG. 4 shows a perspective view 100_1A of a first stage FST included in a spintronics device 200 shown in FIG. 3 as viewed in a first direction DR1, and FIG. 5 shows a front view 100_1B of the first stage shown in FIG. 4 as viewed in a second direction DR2.

Referring to FIGS. 1, 3, 4, and 5, the spintronics device 200 includes a first stage FST, a second stage SST, and a conductive channel (e.g., a conductive channel including elements 103a, 103b, and 103c) for electrically connecting the first stage FST and the second stage SST.

The first stage FST includes a first conductive channel including a plurality of branches (or first current paths, 101a, 101b, and 101c) and a first double-filtering-based spin element 100_1. The second stage SST includes a second conductive channel including a plurality of branches (or second current paths, 103a, 103b, and 103c) and a second double-Filtering-based spin element 100_2.

The second double-filtering-based spin element 100_2 includes a third electrode 110a, a third magnetic layer 120a stacked on the third electrode 110a, a third spin injection layer 130a stacked on the third magnetic layer 120a, a second SCC layer 140a stacked on the third spin injection layer 130a, a fourth spin injection layer 150a stacked on the second SCC layer 140a, a fourth magnetic layer 160a stacked on the fourth spin injection layer 150a, and a fourth electrode 170a stacked on the fourth magnetic layer 160a.

Electrons that have passed through the third ferromagnetic layer 120a and the third spin injection layer 130a are called third passing electrons, electrons that have passed through the second SCC layer 140a and the fourth spin injection layer 150a are called fourth passing electrons, and electrons reflected from a fourth ferromagnetic layer 160a are called second reflected electrons.

Each of the third magnetic layer 120a and the fourth magnetic layer 160a includes a ferromagnet or a ferromagnetic material.

The double-filtering-based spin elements 100, 100_1, and 100_2 are the same as each other in structure and operation.

The first stage FST includes a second dielectric layer 180_2 formed between a first conductive channel-a second branch 101b through which an input current Icin flows and the other end (or a fourth portion) PT4 of the second ferromagnetic layer 160. One end (or a third portion) PT3 of the second ferromagnetic layer 160 is formed between the second spin injection layer 150 and the second electrode 170.

The first stage FST includes a first dielectric layer 180_1 formed between a first conductive channel-third branch 101c and the other end (or a second portion) PT2 of the first ferromagnetic layer 120. A first conductive channel-first branch 101a is connected to the first conductive channel-second branch 101b and the first conductive channel-third branch 101c. One end (or a first portion) PT1 of the first ferromagnetic layer 120 is formed between the first electrode 110 and the first spin injection layer 130.

The second stage SST includes a fourth dielectric layer 182_2 formed between a second conductive channel-second branch 103b and the other end (or an eighth portion) PT8 of the fourth ferromagnetic layer 160a. One end (or a seventh portion) PT7 of the fourth ferromagnetic layer 160a is formed between the fourth spin injection layer 150a and the fourth electrode 170a. The operating voltage Vdd is supplied to the fourth electrode 170a.

The second stage SST includes a third dielectric layer 182_1 formed between a second conductive channel-third branch 103c and the other end (or a sixth portion) PT6 of the third ferromagnetic layer 120a. A second conductive channel-first branch 103a is connected to the second conductive channel-second branch 103b and the second conductive channel-third branch 103c. The second conductive channel-first branch 103a is connected to the SCC layer 140, and one end (or a fifth portion) PT5 of the third ferromagnetic layer 120a is formed between the third electrode 110a and the third spin injection layer 130a. The third electrode 110a is connected to the ground Vss.

According to an embodiment, the elements 101a, 101b, 101c, 103a, 103b, 103c, 140, and 140a may be the same material. According to another embodiment, first elements 101a, 101b, 101c, 103a, 103b, and 103c and second elements 140 and 140a may be different materials. For example, each of the first conductive channel and the second conductive channel may be a conductive material or an electrode.

Each of the dielectric layers 180_1, 180_2, 182_1, and 182_2 may be a ferroelectric material or an antiferroelectric material.

Referring to FIGS. 1 to 5, when the input current Icin is supplied through the first conductive channel-first branch 101a, a magnetic anisotropy energy of the second ferroelectric layer 180_2 may be reduced due to a voltage of the second dielectric layer 180_2, for example, the second ferroelectric layer 180_2, an electric polarization phenomenon, or a magnetoelectric effect, thereby changing a magnetization direction of the second ferromagnetic layer 160.

At this time, when the operating voltage Vdd is supplied to the second electrode 170, the spin current generated according to a magnetization of the second ferromagnetic layer 160 is supplied to the SCC layer 140 through the second spin injection layer 150, and as spin-to-charge conversion occurs within the SCC layer 140, the output current Icout may be induced in the second conductive channel.

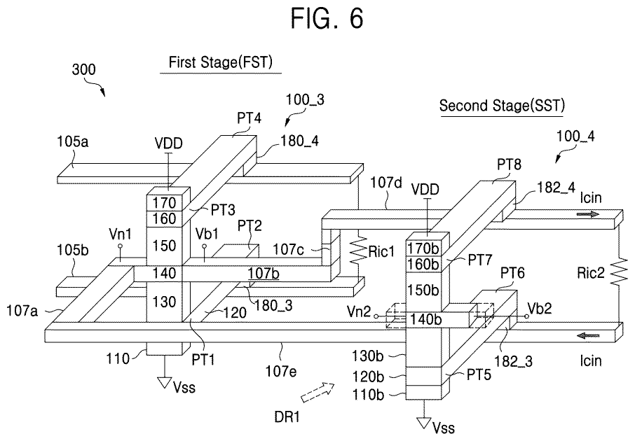

Although, in FIG. 3 and FIG. 6, the operating voltage Vdd supplied to the second electrode 170 and the operating voltage Vdd supplied to the fourth electrode 170a or 170b are indicated as the same voltage, the two operating voltages may be different according to embodiments.

The magnetization direction of the second ferromagnetic layer 160 is determined by Ampere's Right-Hand Rule according to a direction of the input current Icin supplied to the first conductive channel-first branch 101a.

As exemplified in FIG. 5, since the input current Icin enters a center of the first ferromagnetic layer 120 and the second ferromagnetic layer 160, the first magnetization direction MS1 of the first ferromagnetic layer 120 and the second magnetization direction MS2 of the second ferromagnetic layer 160 are generated to be opposite to each other.

A function of the first double-filtering-based spin element 100_1, that is, a difference between the voltages Vn1 and Vb on the right and left sides of the SCC layer 140 (referred to as ‘sensing margin’) increases due to double-filtering.

Referring to FIG. 5, a direction of the current Icin at the the first conductive channel-second branch 101b is an outgoing direction (⊙), and the direction of the current Icin at the the first conductive channel-third branch 101c is also an outgoing direction (⊙).

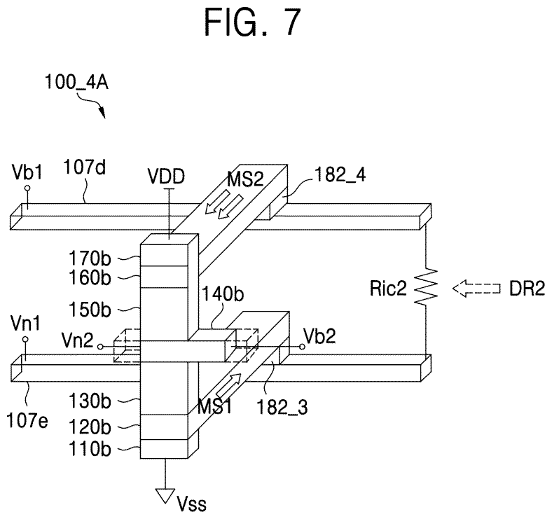

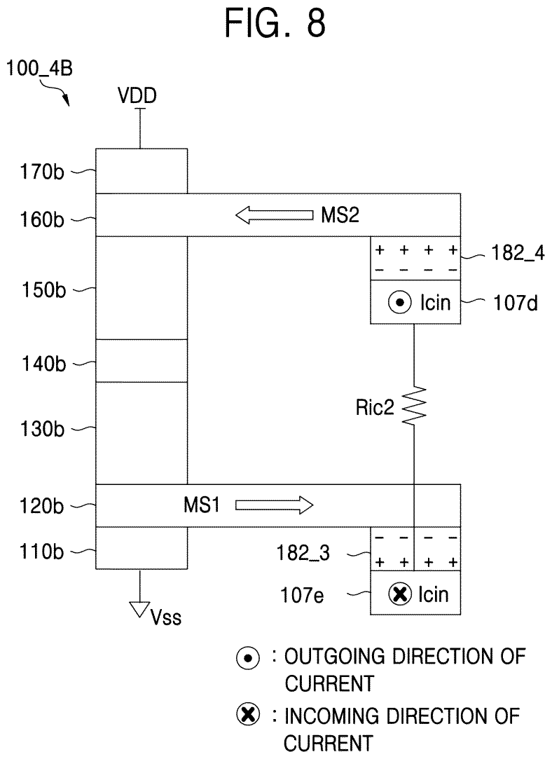

FIG. 6 is another embodiment of the spintronics device including the double-filtering-based spin element shown in FIG. 1, FIG. 7 is a perspective view of a second stage included in the spintronics device shown in FIG. 6 as viewed in the first direction, and FIG. 8 is a front view of the second stage in FIG. 7 as viewed in the second direction.

For example, FIG. 7 shows a perspective view 100_4A of the second stage SST included in a spintronics device 300 shown in FIG. 6 as viewed in the first direction DR1, and FIG. 8 shows a front view 100_4B of the second stage SST shown in FIG. 7 as viewed in the second direction DR2.

Referring to FIGS. 1, 6, 7, and 8, the spintronics device 300 includes a first stage FST, the second stage SST, and a conductive channel electrically connecting the first stage FST and the second stage SST (e.g., a conductive channel including 107a to 107e).

The first stage FST includes a first conductive channel 105a, a second conductive channel 105b, a first resistor Ric1, and a first double-filtering-based spin element 100_3. The second stage SST includes a third conductive channel 107d, a fourth conductive channel 107e, a second resistor Ric2, and a second double-filtering-based spin element 100_4.

A static current, instead of a spike current, may be output by the first resistor Ric1 connected between the first conductive channel 105a and the second conductive channel 105b. In addition, a static current, instead of a spike current, may be output by the second resistor Ric2 connected between the third conductive channel 107d and the fourth conductive channel 107e.

The third conductive channel 107d and the fourth conductive channel 107e are electrically connected through a first conductor 107a, the SCC layer 140, a second conductor 170b, a third conductor 107c, and the second resistor Ric2, so that a current path is formed by them.

The second double-filtering-based spin element 100_4 includes a third electrode 110b, a third magnetic layer 120b stacked on the third electrode 110b, a third spin injection layer 130b stacked on the third magnetic layer 120b, a second SCC layer 140b stacked on the third spin injection layer 130b, a fourth spin injection layer 150b stacked on the second SCC layer 140b, a fourth magnetic layer 160b stacked on the fourth spin injection layer 150b, and a fourth electrode 170b stacked on the fourth magnetic layer 160b.

Electrons that have passed through the third ferromagnetic layer 120b and the third spin injection layer 130b are called third passing electrons, electrons that have passed through the second SCC layer 140b and the fourth spin injection layer 150b are called fourth passing electrons, and electrons reflected from the fourth magnetic layer 160b are called second reflected electrons.

Each of the third magnetic layer 120b and the fourth magnetic layer 160b includes a ferromagnet or a ferromagnetic material.

The double-filtering-based spin elements 100, 100_3, and 100_4 are the same as each other in structure and operation.

The first stage FST includes a second dielectric layer 180_4 formed between the first conductive channel 105a and the other end (or the fourth portion) PT4 of the second ferromagnetic layer 160, and a first dielectric layer 180_3 formed between the second conductive channel 105b and the other end (or the second portion) PT2 of the first ferromagnetic layer 120.

The second stage SST includes a fourth dielectric layer 182_4 formed between the other end (or an eighth portion) PT8 of the fourth ferromagnetic layer 160b and the third conductive channel 107d, and a third dielectric layer 182_3 formed between the other end (or a sixth portion) PT6 of the third ferromagnetic layer 120b and the fourth conductive channel 107e.

According to an embodiment, the elements 105a, 105b, 107a, 107b, 107c, 107d, 107e, 140, and 140b may be the same material. According to another embodiment, first elements 105a, 105b, 107a, 107b, 107c, 107d, and 107e and second elements 140 and 140b may be different materials.

Each of the dielectric layers 180_3, 180_4, 182_3, and 182_4 may be a ferroelectric material or an antiferroelectric material.

Referring to FIGS. 6 to 8, the direction of the current Icin is determined by a difference between the voltage Vn1 on the left side and the voltage Vb1 on the right side of the SCC layer 140.

According to the direction of the current Icin flowing through each of the conductive channels 107d and 107e, the magnetization directions MS1 and MS2 of the ferromagnetic layers 120b and 160b are determined by Ampere's Right-Hand Rule.

Since the directions of the current Icin that switch the magnetization directions MS1 and MS2 of the ferromagnetic layers 120b and 160b are opposite to each other, the first magnetization direction MS1 of the third ferromagnetic layer 120b and the second magnetization direction MS2 of the fourth ferromagnetic layer 160b are generated to be opposite to each other.

Referring to FIG. 8, the direction of the current Icin of the third conductive channel 107d is an outgoing direction (⊙), and the direction of the current Icin of the fourth conductive channel 107c is an incoming direction (⊗).

A function of the second double-filtering-based spin element 100_4, that is, a difference between voltages Vn2 and Vb2 on both sides of the second SCC layer 140b due to double-filtering, i.e., a sensing margin, increases, so that respective magnetization directions MS1 and MS2 of the ferromagnetic layers 120b and 160b may be stably switched based on a static current.

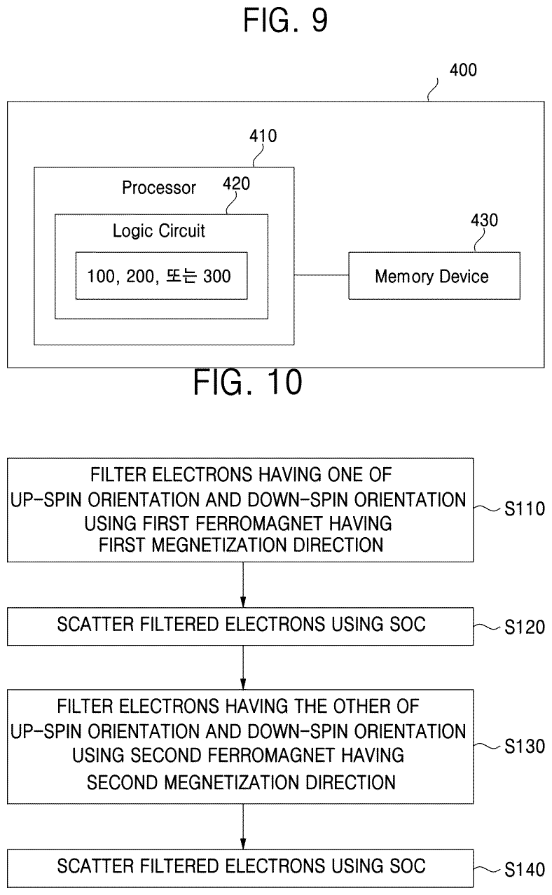

FIG. 9 is a block diagram of a semiconductor device including the double-filtering-based spin element shown in FIG. 1.

Referring to FIG. 9, a semiconductor device (or a semiconductor system) 400 includes a processor 410 and a memory device 430. The processor 410 includes a logic circuit 420, and the logic circuit 420 may include the double-filtering-based spin element 100 shown in FIG. 1, the spintronics device 200 shown in FIG. 3, or the spintronics device 300 shown in FIG. 6. For example, the semiconductor device 400 may be a processing-in-memory (PIM).

The processor 410 may be a central processing unit (CPU), a graphics processing unit (GPU), a tensor processing unit (TPU), an application-specific integrated circuit (ASIC), a field-programmable gate array (FPGA), or a neural processing unit (NPU).

The logic circuit 420 may be implemented as an integrated circuit (IC), and the logic circuit 420 may include at least one of an inverter a buffer, a logic gate circuit operating based on Boolean Algebra, a combinational logic circuit, a sequential logic circuit, a neuromorphic computing accelerator, and an arithmetic logic unit (ALU), or a circuit combining these. The circuit described above may include the double-filtering-based spin element 100.

A logic gate (e.g., an AND gate, an OR gate, a NOT gate, a NAND gate, a NOR gate, or the like) including the double-filtering-based spin element 100 may be a spin valve logic gate, a spin-transfer-torque (STT) logic gate, a spin wave logic gate, a magnon logic gate, a spin diode-based logic gate, a spin-charge coupling logic gate, a non-volatile spin logic gate, or a multi-value logic gate, but the logic gate is not limited thereto.

FIG. 10 is a flowchart for describing the operation of the double-filtering-based spin element shown in FIG. 1.

Referring to FIG. 1, FIG. 2, and FIG. 10, the double-filtering-based spin element 100 filters electrons having one of the first spin orientation (or the up-spin orientation) and the second spin orientation (or the down-spin orientation) by using the first ferromagnet 120 having the first magnetization direction ((A) of FIG. 2 and S110).

The double-filtering-based spin element 100 scatters the filtered electrons using SOC in the SCC layer 140, so that an electric field E is generated within the SCC layer 140 ((B) of FIG. 2, (C) of FIG. 2, and S120).

The double-filtering-based spin element 100 uses a second ferromagnet 160 having the second magnetization direction to filter out electrons having the other of the first spin orientation and the second spin orientation among the scattered electrons ((C) of FIG. 2 and S130).

The double-filtering-based spin element 100 scatters the filtered electrons using the SOC in the SCC layer 140, so that an electric field E is generated within the SCC layer 140 ((D) of FIG. 2 and S140).

The double-filtering-based spin element according to the embodiment of the present disclosure may increase a sensing margin using a double ferromagnetic structure, thereby stably transmitting data to a next logic circuit.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A double-filtering-based spin element comprising:
a first magnetic layer;
a second magnetic layer;
a spin-to-charge conversion layer formed between the first magnetic layer and the second magnetic layer and generating an electric field by performing spin-orbit coupling on first passing electrons and reflected electrons;
a first spin injection layer configured to receive the first passing electrons that have passed through the first magnetic layer and inject the first passing electrons into the spin-to-charge conversion layer; and
a second spin injection layer configured to receive the reflected electrons reflected from the second magnetic layer among second passing electrons that have passed through the spin-to-charge conversion layer and inject the reflected electrons into the spin-to-charge conversion layer.

2. The double-filtering-based spin element of claim 1,
wherein the first magnetic layer generates the first passing electrons by filtering electrons having different spin orientations according to a magnetization direction of the first magnetic layer, and
wherein the second magnetic layer generates the reflected electrons by filtering the second passing electrons having different spin orientations according to a magnetization direction of the second magnetic layer.

3. The double-filtering-based spin element of claim 1,
wherein the magnetization direction of the first magnetic layer and the magnetization direction of the second magnetic layer are opposite to each other.

4. The double-filtering-based spin element of claim 1,
wherein the first magnetic layer and the second magnetic layer include a ferromagnet.

5. A spintronics device comprising:
a first stage;
a second stage; and
a conductive channel connected to the first stage and the second stage,
wherein the first stage includes:
a first magnetic layer including a first portion and a second portion,
a second magnetic layer including a third portion and a fourth portion,
a first spin-to-charge conversion layer formed between the first portion and the third portion and generating a first electric field by performing spin-orbit coupling on first passing electrons and first reflected electrons,
a first spin injection layer formed between the first portion and the first spin-to-charge conversion layer and injecting the first passing electrons that have passed through the first magnetic layer into the first spin-to-charge conversion layer, and
a second spin injection layer formed between the first spin-to-charge conversion layer and the third portion and injecting the first reflected electrons reflected from the second magnetic layer among second passing electrons that have passed through the first spin-to-charge conversion layer into the first spin-to-charge conversion layer.

6. The spintronics device of claim 5,
wherein the first magnetic layer generates the first passing electrons by filtering first electrons having different spin orientations according to a magnetization direction of the first magnetic layer,
wherein the second magnetic layer generates the first reflected electrons by filtering the second passing electrons having different spin orientations according to a magnetization direction of the second magnetic layer, and
wherein the magnetization direction of the first magnetic layer and the magnetization direction of the second magnetic layer are opposite to each other.

7. The spintronics device of claim 6,
wherein the conductive channel includes a first branch connected to the first spin-to-charge conversion layer, and a second branch and a third branch respectively connected to the first branch,
wherein the second stage includes:
a third magnetic layer including a fifth portion and a sixth portion,
a fourth magnetic layer including a seventh portion and an eighth portion,
a second spin-to-charge conversion layer formed between the fifth portion and the seventh portion and generating a second electric field by performing spin-orbit coupling on third passing electrons and second reflected electrons,
a third spin injection layer formed between the fifth portion and the second spin-to-charge conversion layer and injecting the third passing electrons that have passed through the third magnetic layer into the second spin-to-charge conversion layer,
a fourth spin injection layer formed between the second spin-to-charge conversion layer and the seventh portion and injecting the second reflected electrons reflected from the fourth magnetic layer among the fourth passing electrons that have passed through the second spin-to-charge conversion layer into the second spin-to-charge conversion layer,
a first dielectric layer connected between the sixth portion and the third branch, and
a second dielectric layer connected between the eighth portion and the second branch.

8. The spintronics device of claim 7,
wherein each of the first dielectric layer and the second dielectric layer includes a ferroelectric material or an antiferroelectric material.

9. The spintronics device of claim 6,
wherein the conductive channel includes a first conductive channel and a second conductive channel respectively connected to the first spin-to-charge conversion layer,
wherein the second stage includes:
a third magnetic layer including a fifth portion and a sixth portion,
a fourth magnetic layer including a seventh portion and an eighth portion,
a second spin-to-charge conversion layer formed between the fifth portion and the seventh portion and generating a second electric field by performing spin-orbit coupling on third passing electrons and second reflected electrons;
a third spin injection layer formed between the fifth portion and the second spin-to-charge conversion layer and injecting the third passing electrons that have passed through the third magnetic layer into the second spin-to-charge conversion layer;
a fourth spin injection layer formed between the second spin-to-charge conversion layer and the seventh portion and injecting the second reflected electrons reflected from the fourth magnetic layer among the fourth passing electrons that have passed through the second spin-to-charge conversion layer into the second spin-to-charge conversion layer,
a first dielectric layer connected between the sixth portion and the first conductive channel,
a second dielectric layer connected between the eighth portion and the second conductive channel, and
a resistor connected between the first conductive channel and the second conductive channel.

10. The spintronics device of claim 9,
wherein each of the first magnetic layer, the second magnetic layer, the third magnetic layer, and the fourth magnetic layer includes a ferromagnetic material, and
wherein each of the first dielectric layer and the second dielectric layer includes a ferroelectric material or an antiferroelectric material.

11. The spintronics device of claim 9,
wherein the first spin-to-charge conversion layer, the second spin-to-charge conversion layer, the first conductive channel, and the second conductive channel are formed of the same material.

12. The spintronics device of claim 9,
wherein a direction of a current flowing through the first conductive channel is determined by a difference between voltages on both sides of the first spin-to-charge conversion layer.

13. The spintronics device of claim 12,
wherein respective magnetization directions of the third magnetic layer and the fourth magnetic layer are determined by the direction of the current.

14. The spintronics device of claim 9,
wherein when a direction of a current flowing through the first conductive channel and a direction of a current flowing through the second conductive channel are opposite to each other, a magnetization direction of the third magnetic layer and a magnetization direction of the fourth magnetic layer are opposite to each other.

15. A method for operating a double-filtering-based spin element, comprising:
supplying electrons filtered by a first ferromagnet having a first magnetization direction to a spin-to-charge conversion layer;
generating a first electric field as spin-orbit coupling is performed on the filtered electrons in the spin-to-charge conversion layer;
supplying reflected electrons reflected by a second ferromagnet having a second magnetization direction among electrons that have passed through the spin-to-charge conversion layer to the spin-to-charge conversion layer; and
generating a second electric field by additionally performing spin-orbit coupling on the reflected electrons in the spin-to-charge conversion layer.

16. The method of claim 15,
wherein the first magnetization direction of the first ferromagnet and the second magnetization direction of the second ferromagnet are opposite to each other.
